(19) United States
(12) Patent Application Publication
(10) Pub. No.: US 2026/0182148 A1
(43) Pub. Date: Jun. 25, 2026

(54) DISPLAY DEVICE, METHOD OF MANUFACTURING THE SAME AND ELECTRONIC DEVICE INCLUDING THE SAME

(71) Applicant: Samsung Display Co., Ltd., Yongin-si (KR)

(72) Inventors: Sun Hee LEE, Yongin-si (KR); Eun Hye KO, Yongin-si (KR); Hyoung Do KIM, Yongin-si (KR); Seung Hun LEE, Yongin-si (KR); Hye Lim CHOI, Yongin-si (KR)

(21) Appl. No.: 19/354,488

(22) Filed: Oct. 9, 2025

(30) Foreign Application Priority Data
Dec. 23, 2024 (KR) 10-2024-0194463

(51) Int. Cl. H10K 59/121; H10K 59/12; H10K 59/124

(52) U.S. Cl. CPC H10K 59/1213; H10K 59/1201; H10K 59/124

(57) ABSTRACT

A display device, a method of manufacturing the display device, and an electronic device including the display device are disclosed. The display device may include a base substrate, a light-emitting element on the base substrate, transistors electrically connected to the light-emitting element on the base substrate. The transistors may include a first transistor element that includes a first active (e.g., electrically active) layer including an oxide semiconductor, a first gate insulation (e.g., electrical insulation) pattern partially covering a top surface of the first active layer, a first gate electrode partially covering a top surface of the first gate insulation pattern, and a first capping gate covering a surface of the first gate electrode and the top surface of the first gate insulation pattern.

### CROSS-REFERENCE TO RELATED APPLICATION

The present application claims priority to and the benefit of Korean Patent Application No. 10-2024-0194463, filed on Dec. 23, 2024, in the Korean Intellectual Property Office, the entire disclosure of which is incorporated herein by reference.

### BACKGROUND

### 1. Field

One or more embodiments of the present disclosure relate to a display device, a method of manufacturing the display device, and an electronic device including the display device. For example, one or more embodiments of the present disclosure relate to a display device including a transistor, a method of manufacturing the display device, and an electronic device including the display device.

### 2. Description of the Related Art

In display devices, such as an organic light emitting diode (OLED) display device and/or a liquid crystal display (LCD) device, a display substrate including thin film transistors (TFTs) and one or more wirings is provided, and a display structure including electrodes and emission layers is formed or provided on the display substrate to provide a display panel.

For example, the TFTs may include an active layer including a semiconductor material and may include a gate insulation layer and a gate electrode overlapping the active layer. Research and development on structures and materials of the TFT to implement stable image quality are ongoing.

### SUMMARY

One or more aspects of embodiments of the present disclosure are directed toward a display device having improved or enhanced operational reliability.

One or more aspects of embodiments of the present disclosure are directed toward a method of manufacturing a display device having improved or enhanced operational reliability.

One or more aspects of embodiments of the present disclosure are directed toward an electronic device including a display device having improved or enhanced operational reliability.

Additional aspects of embodiments will be set forth in part in the description which follows and, in part, will be apparent from the description or may be learned by practice of the presented embodiments of the disclosure.

A display device may include a base substrate, a light-emitting element on the base substrate, transistor elements electrically connected to the light-emitting element on the base substrate. The transistors may include a first transistor element that includes a first active (e.g., electrically active) layer including an oxide semiconductor, a first gate insulation (e.g., electrical insulation) pattern partially covering a top surface of the first active layer, a first gate electrode partially covering a top surface of the first gate insulation pattern, and a first capping gate covering a surface of the first gate electrode and the top surface of the first gate insulation pattern.

In one or more embodiments, the first capping gate may include a material having a higher resistivity (e.g., electrical resistivity) than the resistivity of the first gate electrode.

In one or more embodiments, the first capping gate may include titanium oxide, tantalum oxide, molybdenum oxide, a transparent (e.g., substantially transparent) conductive (e.g., electrically conductive) oxide (TCO), and/or an oxide semiconductor material.

In one or more embodiments, the first gate insulation pattern may include an overlap portion covered by the first gate electrode and a first shoulder portion and a second shoulder portion which are not covered by the first gate electrode. The first shoulder portion and the second shoulder portion may be opposite to (e.g., face) each other with the overlap portion therebetween.

In one or more embodiments, the first capping gate may contact top surfaces of the first shoulder portion and the second shoulder portion (e.g., a top surface of the first shoulder portion and a top surface of the second shoulder portion).

In one or more embodiments, the first capping gate may be continuously (e.g., substantially continuously) formed or provided on the top surface of the first shoulder portion, a side surface of the first gate electrode, a top surface of the first gate electrode, and the top surface of the second shoulder portion.

In one or more embodiments, the first active layer may have a width greater than the width of the first gate insulation pattern. The first active layer may include a first channel region overlapping the first gate insulation pattern, a first contact region protruding from the first shoulder portion, and a second contact region protruding from the second shoulder portion.

In one or more embodiments, the display device may further include a first contact electrode and a second contact electrode that are electrically connected to the first contact region and the second contact region, respectively.

In one or more embodiments, the display device may further include a first gate contact penetrating the first capping gate and contacting a top surface of the first gate electrode.

In one or more embodiments, the first transistor element may be provided as a driving transistor.

In one or more embodiments, the transistor elements may further include a second transistor element. The second transistor element may include a second active (e.g., electrically active) layer, a second gate insulation (e.g., electrical insulation) pattern partially covering a top surface of the second active layer, a second gate electrode on the second gate insulation pattern, and a second capping gate on a top surface of the second gate electrode. The second capping gate may not be in contact with the second gate insulation pattern.

In one or more embodiments, the second capping gate may not cover a side surface of the second gate electrode.

In one or more embodiments, the second active layer may include the oxide semiconductor.

In one or more embodiments, the second transistor element may be provided as a switching transistor.

In a method of manufacturing a display device, a first active (e.g., electrically active) layer including an oxide semiconductor and a second active (e.g., electrically active) layer may be formed or provided on a base substrate. A gate insulation (e.g., electrical insulation) layer covering the first active layer and the second active layer may be formed or provided on the base substrate. A first gate electrode and a second gate electrode that are overlapping the first active layer and the second active layer, respectively, may be formed or provided on the gate insulation layer. A capping gate layer covering the first gate electrode and the second gate electrode may be formed or provided on the gate insulation layer. A first photoresist pattern covering the first gate electrode and having a width greater than a maximum width of the first gate electrode and a second photoresist pattern overlapping the second gate electrode and having a width less than a maximum width of the second gate electrode may be formed or provided on the capping gate layer. The capping gate layer may be etched utilizing the first photoresist pattern and the second photoresist pattern as etching masks (e.g., a first set of etching masks) to form or provide a first capping gate covering the first gate electrode and a second capping gate on a top surface of the second gate electrode. The gate insulation layer may be etched to form or provide a first gate insulation (e.g., electrical insulation) pattern between the first gate electrode and the first active layer and a second gate insulation (e.g., electrical insulation) pattern between the second gate electrode and the second active layer. A light-emitting element electrically connected to the first active layer may be formed or provided.

In one or more embodiments, in the etching of the gate insulation layer, the first capping gate and the second capping gate may be utilized as etching masks (e.g., a second set of etching masks) together with the first photoresist pattern and the second photoresist pattern.

In one or more embodiments, the first active layer and the second active layer may comprise the oxide semiconductor.

In one or more embodiments, the capping gate layer may be formed or provided to have a resistivity (e.g., electrical resistivity) greater than the resistivity of the first gate electrode and the second gate electrode.

An electronic device includes a display device, a memory, and a processor to execute data included in the memory and control an operation of the display device. The display device may include a base substrate, a light-emitting element on the base substrate, and a transistor element electrically connected to the light-emitting element on the base substrate. The transistor element may include an active (e.g., electrically active) layer including an oxide semiconductor, a gate insulation (e.g., electrical insulation) pattern partially covering a top surface of the active layer, a gate electrode partially covering a top surface of the gate insulation pattern, and a capping gate covering a surface of the gate electrode and the top surface of the gate insulation pattern.

In one or more embodiments, the electronic device may include a virtual reality glass, an augmented reality glass, a smart phone, a tablet PC, a laptop, a TV, a desk monitor, smart glasses, a head-mounted display, a smart watch, and/or a vehicle display.

In a display device according to one or more embodiments of the present disclosure, a capping gate covering a gate electrode and covering a top surface of a side region of a gate insulation (e.g., electrical insulation) pattern may be formed or provided on the gate electrode partially covering the gate insulation pattern. A resistance (e.g., electrical resistance) of the side region may be increased by the capping gate, so that (e.g., such that) a current sensitivity according to a voltage change of a transistor may be reduced.

Thus, deterioration of a display quality, such as an image stain caused by high sensitivity of an oxide semiconductor, may be suppressed (or a degree or occurrence of deterioration of a display quality, such as an image stain caused by high sensitivity of an oxide semiconductor, may be reduced).

### BRIEF DESCRIPTION OF THE DRAWINGS

The accompanying drawings, together with the specification, illustrate embodiments of the subject matter of the present disclosure, and, together with the description, serve to explain principles of embodiments of the subject matter of the present disclosure.

FIG. 1 is a schematic cross-sectional view of a display panel or a display device including a transistor element according to one or more embodiments.

FIG. 2 is a schematic cross-sectional view of a display panel or a display device including a transistor element according to one or more embodiments.

FIG. 3 is a graph illustrating changes in a gate-source voltage and a drain-source current of transistor elements according to Example and Comparative Example.

FIG. 4 is a schematic cross-sectional view illustrating a display device according to one or more embodiments.

FIG. 5 is a schematic cross-sectional view illustrating a display device according to one or more embodiments.

FIGS. 6-12 are schematic cross-sectional views describing a method of manufacturing a display panel or a display device according to one or more embodiments.

FIG. 13 is an exploded perspective view illustrating an electronic device according to one or more embodiments.

FIG. 14 is a schematic plan view illustrating an arrangement of pixels of a display device included in an electronic device according to one or more embodiments.

FIG. 15 is a pixel equivalent circuit diagram of a display device according to one or more embodiments.

FIG. 16 is a block diagram of an electronic device in accordance with one or more embodiments.

FIG. 17 is a schematic diagram of electronic devices in accordance with one or more embodiments.

### DETAILED DESCRIPTION

The subject matter of the present disclosure will be described more fully hereinafter with reference to the accompanying drawings, in which embodiments of the present disclosure are shown. The subject matter of the present disclosure may, however, be embodied in different forms and should not be construed as being limited to one or more embodiments set forth herein. Rather, these embodiments are provided as examples so that this disclosure will be thorough and complete, and will fully convey the aspects and features of the present disclosure to those skilled in the art.

Like reference numerals denote like elements throughout the descriptions.

The utilization of “may” if (e.g., when) describing embodiments of the present disclosure refers to “one or more embodiments of the present disclosure.”

In the context of the present disclosure and unless otherwise defined, the terms, “use,” “using,” and “used,” may be considered synonymous with the terms, “utilize,” “utilizing,” and “utilized,” respectively.

As used herein, the term, “and/or,” includes any and all combinations of one or more of the associated listed items. For example, “A and/or B” indicates cases where it is A, B, or both (e.g., simultaneously) A and B.

Throughout the present disclosure, the expression “at least one of a, b, or c” indicates only a, only b, only c, both (e.g., simultaneously) a and b, both (e.g., simultaneously) a and c, both (e.g., simultaneously) b and c, all of a, b, and c, or variations thereof.

The singular forms, “a,” “an,” and “the,” include plural references unless the context clearly requires otherwise.

In the present disclosure, it will be understood that the term “comprise(s)/comprising,” “include(s)/including,” or “have/has/having” specifies the presence of stated features, integers, steps, operations, elements, and/or components, but do not preclude the presence or addition of one or more other features, integers, steps, operations, elements, components, and/or groups thereof. Also, the terms “comprise(s)/comprising,” “include(s)/including,” “have/has/having,” or similar terms include or support the terms “consisting of” and “consisting essentially of,” indicating the presence of stated features, integers, steps, operations, elements, and/or components, without or essentially without the presence of other features, integers, steps, operations, elements, components, and/or groups thereof.

The terms, “on”, “connected”, “coupled,” and/or the like, used herein refers to a direct placement/connection/combination and also refers to a case where another element is between two different elements.

The terms, such as “first”, “second”, “below”, “below”, “above,” “above,” and/or the like, are used in a relative sense to distinguish different elements or positions and do not specify an absolute position or an absolute order.

As used herein, the terms, “substantially,” “about,” and/or the like, are used as terms of approximation and not as terms of degree and are intended to account for the inherent deviations in measured or calculated values that would be recognized by those of ordinary skill in the art.

Any numerical range recited herein is intended to include all sub-ranges of the same numerical precision subsumed within the recited range. For example, a range of “1.0 to 10.0” is intended to include all subranges between (and including) the recited minimum value of 1.0 and the recited maximum value of 10.0, for example, having a minimum value equal to or greater than 1.0 and a maximum value equal to or less than 10.0, such as, for example, 2.4 to 7.6. Any maximum numerical limitation recited herein is intended to include all lower numerical limitations subsumed therein, and any minimum numerical limitation recited in the present disclosure is intended to include all higher numerical limitations subsumed therein. Accordingly, Applicant reserves the right to amend this specification, including the claims, to expressly recite any sub-range subsumed within the ranges expressly recited herein.

In the context of the present disclosure and unless otherwise defined, plan view is an orthographic projection of a three-dimensional object from the position of a horizontal plane that intersects the object. For example, it is a top-down view, illustrating the layout and spatial relationships of one or more elements within the object or structure. A plan view based on a z-axis (thickness) direction refers to a top-down view of the object, as if (e.g., when) looking directly down onto the surface from above. In this context, the z-axis direction is perpendicular or normal to the horizontal plane defined by x-axis and y-axis directions.

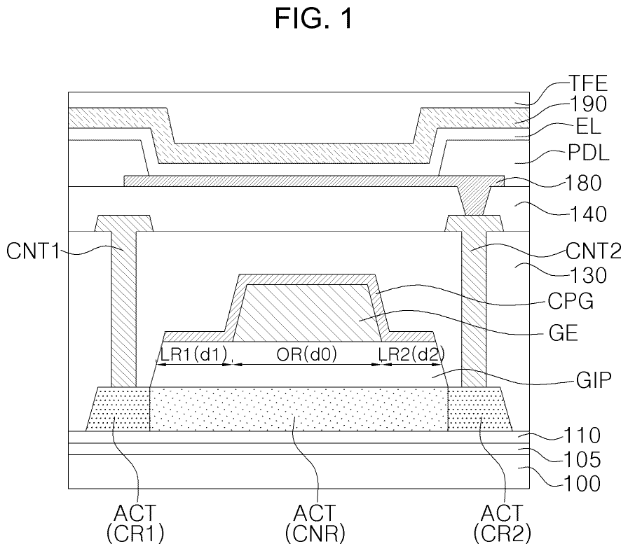

FIG. 1 is a schematic cross-sectional view of a display panel or a display device including a transistor element according to one or more embodiments.

Referring to FIG. 1, a transistor element of a thin film transistor (TFT) type or kind including an active layer ACT may be on a base substrate 100. According to one or more embodiments, a plurality of transistor elements may be arranged or provided on the base substrate 100 to provide a display panel in the form of a TFT-array substrate and a display device including the display panel.

The display panel or the display device may include a light-emitting element connected to the transistor element, and the light-emitting element may be electrically connected to the transistor element through a contact electrode.

The base substrate 100 may be provided as a back-plane substrate of the display device or the display panel. A glass substrate and/or a plastic substrate may be used as the base substrate 100.

In one or more embodiments, the base substrate 100 may include a polymer material having transparency and flexibility. For example, the base substrate 100 may include a polymer material, such as polyimide, polysiloxane, an epoxy resin, an acrylic resin, polyester, and/or the like. In one or more embodiments, the base substrate 100 may include polyimide.

In one or more embodiments, a glass substrate may be used as the base substrate 100.

A barrier layer 105 may be formed or provided on a top surface of the base substrate 100. Moisture that penetrates through the base substrate 100 may be blocked (or a degree to or occurrence of which moisture penetrates through the base substrate 100 may be reduced) by the barrier layer 105, and diffusion of impurities between the structures on the base substrate 100 and the base substrate 100 may be blocked (or a degree or occurrence of diffusion of impurities between the structures on the base substrate 100 and the base substrate 100 may be reduced). The barrier layer 105 may entirely (e.g., substantially entirely) cover the top surface of the base substrate 100.

The barrier layer 105 may include, for example, an inorganic insulating (e.g., electrically insulating) material, such as silicon oxide, silicon nitride, and/or silicon oxynitride. These inorganic insulating materials may be used alone or in a combination of two or more therefrom. In one or more embodiments, the barrier layer 105 may have a stacked structure including a silicon oxide layer and/or a silicon nitride layer. In one or more embodiments, the barrier layer 105 may include an organic layer and may have a multi-layered structure of an organic layer and an inorganic layer.

A buffer layer 110 may be further provided on a top surface of the barrier layer 105. Penetration of impurities into the active layer ACT of the thin film transistor may be additionally prevented (or a degree or occurrence of penetration of impurities into the active layer ACT of the thin film transistor may be additionally reduced) by the buffer layer 110. The buffer layer 110 may include an inorganic insulating (e.g., electrically insulating) material, such as silicon nitride, silicon oxide, and/or silicon oxynitride. The buffer layer 110 may have a single-layered structure or a multi-layered structure including the inorganic insulating material as described in one or more embodiments.

A transistor element may be on the buffer layer 110. The transistor element may include an active layer ACT and a gate electrode GE. A gate insulation pattern GIP may be between the active layer ACT and the gate electrode GE.

According to one or more embodiments of the present disclosure, the active layer ACT may include an oxide semiconductor, such as indium gallium zinc oxide (IGZO), zinc tin oxide (ZTO), indium tin zinc oxide (ITZO), indium tin gallium zinc oxide (ITGZO), and/or the like.

The active layer ACT may include a channel region CNR and contact regions CR1 and CR2. The contact regions CR1 and CR2 may have a conductivity (e.g., electrical conductivity) greater than the conductivity of the channel region CNR. For example, the contact regions CR1 and CR2 may have a higher impurity concentration and/or a higher carrier concentration (e.g., a hydrogen concentration) than the impurity concentration and/or a carrier concentration (e.g., a hydrogen concentration) of the channel region CNR.

The contact regions CR1 and CR2 may include a first contact region CR1 and a second contact region CR2. A region between the first contact region CR1 and the second contact region CR2 may be defined as the channel region CNR. For example, the first contact region CR1 and the second contact region CR2 may be formed or provided at one side portion and the other side portion or at one end portion and the other end portion of the channel region CNR, respectively.

The contact regions CR1 and CR2 may serve as source/drain regions. For example, the first contact region CR1 and the second contact region CR2 may serve as a source region and a drain region, respectively.

The gate insulation pattern GIP may be on the active layer ACT to substantially cover the channel region CNR of the active layer ACT. The gate insulation pattern GIP may partially cover the active layer ACT. Thus, the contact regions CR1 and CR2 may protrude from the gate insulation pattern GIP in plan view. For example, a portion of the active layer ACT covered by the gate insulation pattern GIP may be substantially defined as the channel region CNR.

The gate insulation pattern GIP may include an inorganic insulating (e.g., electrically insulating) material, such as silicon oxide, silicon nitride, silicon oxynitride, aluminum oxide, titanium oxide, tantalum oxide, hafnium oxide, and/or the like.

The gate electrode GE may be on the gate insulation pattern GIP. The gate electrode GE may overlap the channel region CNR in a thickness direction with the gate insulation pattern GIP therebetween.

The gate electrode GE may include a metal, such as silver (Ag), tungsten (W), molybdenum (Mo), aluminum (Al), copper (Cu), titanium (Ti), chromium (Cr), nickel (Ni), tantalum (Ta), platinum (Pt), palladium (Pd), and/or the like, or an alloy containing at least one thereof. The gate electrode GE may have a single-layered structure or a multi-layered structure including the metal as described in one or more embodiments. For example, the gate electrode GE may include a sequential stacked structure of a first metal layer (e.g., a Ti layer), a second metal layer (e.g., an Al layer), and a third metal layer (e.g., a Ti layer).

The gate electrode GE may partially cover the gate insulation pattern GIP. According to one or more embodiments, the gate electrode GE may partially cover a top surface of the gate insulation pattern GIP, and a side portion or an edge portion of the top surface of the gate insulation pattern GIP and a side surface of the gate insulation pattern GIP may not be covered by the gate electrode GE.

According to one or more embodiments, the gate insulation pattern GIP may include an overlap portion OR substantially overlapping the gate electrode GE in a thickness direction and a shoulder portion corresponding to a side portion not covered by the gate electrode GE. The shoulder portion may include a first shoulder portion LR1 and a second shoulder portion LR2 that are opposite to (e.g., facing) each other with the overlap portion OR therebetween.

According to one or more embodiments of the present disclosure, the transistor element may further include a capping gate CPG formed or provided on the gate electrode GE and the gate insulation pattern GIP. The capping gate CPG may be on a surface of the gate electrode GE and a top surface of the shoulder portion. The capping gate CPG may directly contact the surface of the gate electrode GE and the top surface of the shoulder portion.

According to one or more embodiments, the capping gate CPG may be formed or provided continuously (e.g., substantially continuously) along a top surface of the first shoulder portion LR1, side surfaces and the top surface of the gate electrode GE, and a top surface of the second shoulder portion LR2. In one or more embodiments, the capping gate CPG may at least partially cover the top surface of the first shoulder portion LR1 and the top surface of the second shoulder portion LR2. In one or more embodiments, the capping gate CPG may entirely (e.g., substantially entirely) cover the top surface of the first shoulder portion LR1 and the top surface of the second shoulder portion LR2.

In one or more embodiments, the capping gate CPG may not cover a side surface of the first shoulder portion LR1 and/or a side surface of the second shoulder portion LR2.

The capping gate CPG may include a material having a higher resistivity (e.g., electrical resistivity) than the resistivity of the gate electrode GE. According to one or more embodiments, the capping gate CPG may include a metal oxide. For example, capping gates (CPG) may include titanium oxide (e.g., TiOₓ, wherein 0<x≤2; e.g., TiO₂), tantalum oxide (e.g., TaOₓ, wherein 0<x≤3; e.g., Ta₂O₅), molybdenum oxide (e.g., MoOₓ, wherein 0<x≤3; e.g., MoO₃), a transparent (e.g., substantially transparent) conductive (e.g., electrically conductive) oxide (TCO)-based material (e.g., indium tin oxide (ITO), indium zinc oxide (IZO), indium tin zinc oxide (ITZO), and/or the like), and/or an oxide semiconductor-based material (e.g., IGZO, ZTO, ITZO, and/or the like). These materials may be used alone or in a combination of two or more therefrom.

A gate resistance (e.g., electrical resistance) on the shoulder portions LR1 and LR2 may be increased by the formation of the capping gate CPG. Accordingly, a voltage drop may be induced on the shoulder portions LR1 and LR2. For example, the capping gate CPG may function as an injection barrier with respect to the gate electrode GE or the overlap portion OR.

For example, the voltage drop on the shoulder portions LR1 and LR2 may be induced by the resistivity (Rs(cpg)) of the capping gate (CPG), and a voltage-current sensitivity of the transistor element including the oxide semiconductor may be lowered.

Thus, excessive or substantial sensitivity of a driving current due to a voltage change may be suppressed or reduced while utilizing high mobility properties of the oxide semiconductor. Therefore, even if (e.g., when) the active layer ACT including the oxide semiconductor is used as a driving transistor, deterioration of image quality, such as an image stain, a low-grayscale image, and/or the like may be prevented (or a degree or occurrence of deterioration of image quality, such as an image stain, a low-grayscale image, and/or the like may be reduced) while sufficiently or suitably achieving operation stability.

As illustrated in FIG. 1, a length of the overlap portion OR (a horizontal length in FIG. 1) is indicated by d0, and lengths of the first shoulder portion LR1 and the second shoulder portion LR2 are indicated by d1 and d2, respectively.

The length d1 of the first shoulder portion LR1 and the length d2 of the second shoulder portion LR2 may each be in a range from about 5% to about 50%, greater than or equal to about 10% and less than or equal to about 50%, or from about 10% to about 40% of the length d0 of the overlap portion OR. In the foregoing ranges, the injection barrier effect as described in one or more embodiments may be implemented while suppressing or reducing an excessive or substantial gate voltage drop.

For example, the transistor element may satisfy Relations 1 and 2.

$$Rs ( cpg ) * d 1 > Rs ( GE ) * d 0 \qquad Relation 1$$

$$Rs ( cpg ) * d 2 > Rs ( GE ) * d 0 \qquad Relation 2$$

In Relations 1 and 2, Rs(cpg) represents a resistivity (e.g., electrical resistivity) of the capping gate CPG, Rs(GE) represents a resistivity (e.g., electrical resistivity) of the gate electrode GE, and d0, d1 and d2 represent the lengths of the overlap portion OR, the first shoulder portion LR1, and the second shoulder portion LR2, respectively, of the gate insulation pattern GIP.

In Relations 1 and 2, the voltage drop effect in the shoulder portions LR1 and LR2 may be substantially implemented.

A thickness of the capping gate CPG may be determined in consideration of the injection barrier effect as described in one or more embodiments and the formation of the gate contact GC as described in one or more embodiments. In one or more embodiments, the thickness of the capping gate CPG may be in a range from about 100 Å to about 300 Å, from about 100 Å to about 200 Å, about 100 Å or more and less than about 200 Å, or from about 150 Å to about 190 Å.

An insulating interlayer 130 may be formed or provided on the base substrate 100 or the buffer layer 110 to cover the transistor element in the form of a thin film transistor including the active layer ACT, the gate insulation pattern GIP, the gate electrode GE, and the capping gate CPG.

The insulating interlayer 130 may include an inorganic insulating (e.g., electrically insulating) material, such as silicon oxide, silicon nitride, silicon oxynitride, aluminum oxide, titanium oxide, tantalum oxide, hafnium oxide, and/or the like. The insulating interlayer 130 may have a single-layered structure or a multi-layered structure including different materials (e.g., silicon oxide and/or silicon nitride).

A contact electrode may penetrate the insulating interlayer 130 to be in contact with or electrically connected to the contact region. The contact electrode may include a first contact electrode CNT1 and a second contact electrode CNT2 which are in contact with or electrically connected to the first contact region CR1 and the second contact region CR2, respectively.

In one or more embodiments, the first contact electrode CNT1 may serve as a source contact or a source electrode, and the second contact electrode CNT2 may serve as a drain contact or a drain electrode.

The first contact electrode CNT1 and the second contact electrode CNT2 may include a metal, such as silver (Ag), tungsten (W), molybdenum (Mo), aluminum (Al), copper (Cu), titanium (Ti), chromium (Cr), nickel (Ni), tantalum (Ta), molybdenum (Mo), platinum (Pt), palladium (Pd), or an alloy containing at least one thereof.

The contact electrodes CNT1 and CNT2 may have a single-layered structure or a multi-layered structure including the metal as described in one or more embodiments. For example, the contact electrodes CNT1 and CNT2 may include a sequential stacked structure of a first metal layer (e.g., a Ti layer), a second metal layer (e.g., an Al layer), and a third metal layer (e.g., a Ti layer).

The contact electrodes CNT1 and CNT2 may include a contact portion penetrating the insulating interlayer 130 and a wiring portion on a top surface of the insulating interlayer 130.

A planarization layer 140 covering the wiring portion of the contact electrodes CNT1 and CNT2 may be formed or provided on the insulating interlayer 130. The planarization layer 140 may include an organic material, such as polyimide, an epoxy resin, an acrylic resin, polyester, a siloxane resin, a benzocyclobutene (BCB) resin, and/or the like.

A display element electrically connected to the transistor element through the contact electrode may be on the planarization layer 140. The display element may include a light-emitting element.

The light-emitting element may include a first electrode 180, a light emitting part EL, and a second electrode 190.

The first electrode 180 may include a via electrode that may be on the planarization layer 140 and may penetrate the planarization layer 140 to be in contact with or connected to the wiring portion of the second contact electrode CNT2.

The first electrode 180 may serve as a pixel electrode or an anode and may include a high work function conductive (e.g., electrically conductive) material that may promote or enhance hole injection. The first electrode 180 may be formed or provided as a transmissive electrode. The first electrode 180 may include a transparent (e.g., substantially transparent) conductive (e.g., electrically conductive) oxide, such as indium tin oxide (ITO), indium zinc oxide (IZO), zinc oxide (e.g., ZnOₓ, wherein 0<x≤2; e.g., ZnO), and indium tin zinc oxide (ITZO).

The first electrode 180 may be formed or provided as a translucent electrode or a reflective electrode. The first electrode 180 may include a metal selected from Ag, magnesium (Mg), Cu, Al, Pt, Pd, gold (Au), Ni, neodymium (Nd), iridium (Ir), Cr, lithium (Li), calcium (Ca), Mo, Ti, W, indium (In), tin (Sn), and zinc (Zn), or an alloy including at least one therefrom.

The first electrode 180 may have a single-layered structure or a multi-layered structure. For example, the first electrode 180 may have a triple-layered structure of ITO/Ag/ITO.

A pixel defining layer PDL may be formed or provided on the planarization layer 140 to at least partially expose a top surface of the first electrode 180. The pixel defining layer PDL may cover a peripheral portion of the first electrode 180.

A light-emitting region may be defined by a sidewall of the pixel defining layer PDL. For example, a green light-emitting region, a blue light-emitting region, and a red light-emitting region may be separated and defined by the pixel defining layer PDL. Accordingly, the light-emitting elements may include a blue light-emitting element, a green light-emitting element, and/or a red light-emitting element.

In one or more embodiments, all of the light-emitting elements may be white light-emitting elements or blue light-emitting elements.

The pixel defining layer PDL may include, for example, an organic material, such as a polysiloxane resin, a polyimide resin, an acrylic resin, and/or the like. The pixel defining layer PDL may include a colorant material, such as a black pigment and/or a dye dispersed in the resin material.

A light-emitting portion EL may be on the first electrode 180 and the pixel defining layer PDL. The light-emitting portion EL may include an organic emission layer that may be independently patterned for each of a red pixel, a green pixel, and a blue pixel to generate different color lights for each of the pixels.

In one or more embodiments, the light-emitting portion EL may continuously (e.g., substantially continuously) and commonly extend throughout a plurality of pixels. In this case, the light-emitting portion EL may include a white emission layer or a blue emission layer. In one or more embodiments, the light-emitting portion EL may include emission layers corresponding to a plurality of different color lights or substantially the same color light and may include a stack having a tandem structure.

The second electrode 190 may be on the light-emitting portion EL. The second electrode 190 may be a common electrode continuously (e.g., substantially continuously) and commonly extending on a plurality of the light-emitting regions or the pixels.

The second electrode 190 may serve as an electron injection electrode or a cathode. The second electrode 190 may include a metal, an alloy, an electrically conductive compound, and/or the like, having a low work function.

For example, the second electrode 190 may include lithium (Li), silver (Ag), magnesium (Mg), aluminum (Al), aluminum-lithium (Al—Li), calcium (Ca), magnesium-indium (Mg—In), magnesium-silver (Mg—Ag), ytterbium (Yb), silver-ytterbium (Ag—Yb), ITO, IZO, and/or the like. These materials may be used alone or in a combination thereof.

The second electrode 190 may be formed or provided as a transmissive electrode, a translucent electrode, or a reflective electrode. The second electrode 190 may have a single-layered structure or a multi-layered structure.

The light-emitting portion EL may further include a hole transport layer and an electron transport layer. According to one or more embodiments, the hole transport layer, the emission layer, the electron transport layer, and the second electrode 190 may be sequentially stacked from a top surface of the first electrode 180.

For example, the hole transport layer may include a hole transporting material, such as 4,4′,4″-[tris(3-methylphenyl)phenylamino] triphenylamine (m-MTDATA), 4,4′4″-tris(N,N-diphenylamino)triphenylamine (TDATA), 4,4′,4″-tris[N(2-naphthyl)-N-phenylamino]-triphenylamine (2-TNATA), N,N′-di(naphthalene-l-yl)-N,N′-diphenyl-benzidine (NPB), N,N′-bis(3-methylphenyl)-N,N′-diphenyl-[1,1′-biphenyl]-4,4′-diamine (TPD), 4,4′,4″-tris(N-carbazolyl)triphenylamine (TCTA), poly(3,4-ethylenedioxythiophene)/poly(4-styrenesulfonate) (PEDOT/PSS), and/or the like.

The electron transport layer may include an electron transporting material, such as an anthracene-based compound, tris(8-hydroxyquinolinato)aluminum (Alq₃), 1,3,5-tri(1-phenyl-1H-benzo[d]imidazol-2-yl)benzene (TPBi), 2,9-dimethyl-4,7-diphenyl-1,10-phenanthroline (BCP), 4,7-diphenyl-1,10-phenanthroline (Bphen), 3-(4-biphenylyl)-4-phenyl-5-tert-butylphenyl-1,2,4-triazole (TAZ), 4-(naphthalen-1-yl)-3,5-diphenyl-4H-1,2,4-triazole (NTAZ), 2-(4-biphenylyl)-5-(4-tert-butylphenyl)-1,3,4-oxadiazole (tBu-PBD), bis(2-methyl-8-quinolinolato-N1,O8)-(1,1′-biphenyl-4-olato)aluminum (BAlq), and/or the like.

In one or more embodiments, a hole injection layer may be further between the first electrode 180 and the hole transport layer. An electron injection layer may be further between the second electrode 190 and the electron transport layer.

In one or more embodiments, the emission layer included in the light-emitting portion EL may be patterned selectively within the light-emitting region defined by the pixel defining layer PDL. Accordingly, the emissions layer may be separated from each other in the form of islands spaced and/or apart (e.g., spaced apart or separated) from each other in each of the plurality of pixels.

In one or more embodiments, the layers (e.g., the hole transport layer and the electron transport layer) included in the light-emitting portion EL may extend continuously (e.g., substantially continuously) and commonly throughout a plurality of the light-emitting regions and the top surface of the pixel defining layer PDL.

An organic light emitting diode (OLED) device may be formed or provided by the first electrode 180, the light-emitting portion EL, and the second electrode 190 as described in one or more embodiments.

An encapsulation layer TFE may be formed or provided on the second electrode 190. The encapsulation layer TFE may be on the pixel defining layer PDL and the light-emitting elements to protect the light-emitting elements from moisture and/or oxygen.

The encapsulation layer TFE may include an inorganic layer including silicon nitride (e.g., SiNₓ, wherein 0<x≤2; e.g., Si₃N₄), silicon oxide (e.g., SiOₓ, wherein 0<x≤2; e.g., SiO₂), indium tin oxide, indium zinc oxide, or any combination thereof; an organic layer including polyethylene terephthalate, polyethylene naphthalate, polycarbonate, polyimide, polyethylene sulfonate, polyoxymethylene, polyarylate, hexamethyldisiloxane, an acrylic resin (e.g., polymethylmethacrylate, polyacrylic acid, and/or the like), an epoxy resin (e.g., aliphatic glycidyl ether (AGE) and/or the like), or a combination thereof; or a combination of the inorganic layer and the organic layer.

The encapsulation layer TFE may be formed or provided in a single-layered structure or a multi-layered structure. In one or more embodiments, the encapsulation layer TFE may have a sequential stacked structure of a first inorganic layer, an organic layer, and a second inorganic layer.

In one or more embodiments, a color control layer overlapping the light-emitting portion EL may be on the encapsulation layer TFE. The color control layer may include a color conversion layer including quantum dots and/or a color filter.

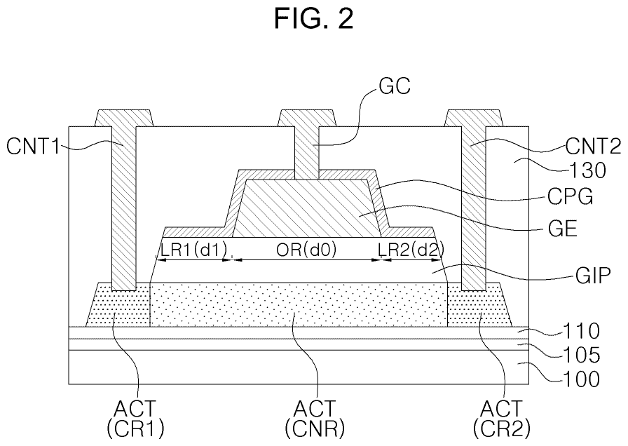

FIG. 2 is a schematic cross-sectional view of a display panel or a display device including a transistor element according to one or more embodiments. More detailed descriptions on elements and structures substantially the same as or similar to those described with reference to FIG. 1 may not be provided. For convenience of illustration, the light-emitting elements as described with reference to FIG. 1 may not be provided.

Referring to FIG. 2, the display device may further include a gate contact GC. The gate contact GC may penetrate the insulating interlayer 130 and may be electrically connected to the gate electrode GE.

According to one or more embodiments, the gate contact GC may penetrate the insulating interlayer 130 and the capping gate CPG and may be in contact with a top surface of the gate electrode GE. A side surface of a bottom portion of the gate contact GC may be surrounded by the capping gate CPG.

The gate contact GC may include substantially the same conductive (e.g., electrically conductive) material and/or metal as the conductive material and/or metal of the contact electrodes CNT1 and CNT2. As will be described herein, the gate contact GC may be formed or provided by substantially the same etching process and deposition process for the formation or arrangement of the contact electrodes CNT1 and CNT2.

In one or more embodiments, bottom portions of the contact electrodes CNT1 and CNT2 may be inserted into or buried in upper portions of the contact regions CR1 and CR2.

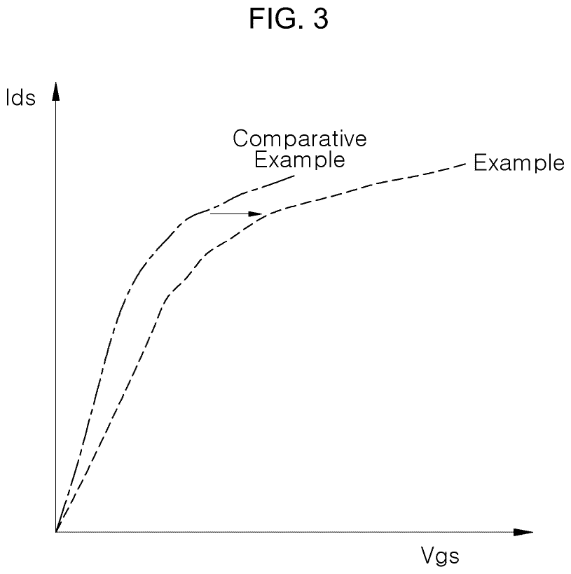

FIG. 3 is a graph illustrating changes in a gate-source voltage and a drain-source current of transistor elements according to Example and Comparative Example.

Referring to FIG. 3, in Comparative Example in which the capping gate CPG is omitted from the transistor element of Example as described with reference to FIG. 1, a relatively steep drain-source current (Ids) curve is obtained with respect to a change in a gate-source voltage (Vgs).

In Example in which the capping gate CPG is added on the shoulder portions LR1 and LR2 of the gate insulation pattern GIP, an injection barrier due to an increased resistivity (e.g., electrical resistivity) of the capping gate CPG may be added as described in one or more embodiments.

Accordingly, a sensitivity of the drain-source current (Ids) to the change in the gate-source voltage (Vgs) is alleviated, and the drain-source current (Ids) curve becomes relatively smooth as illustrated in FIG. 3.

Therefore, a driving section in a relatively low current region may be achieved, and image stains and low gradation phenomena in a driving transistor using the oxide semiconductor may be reduced or suppressed.

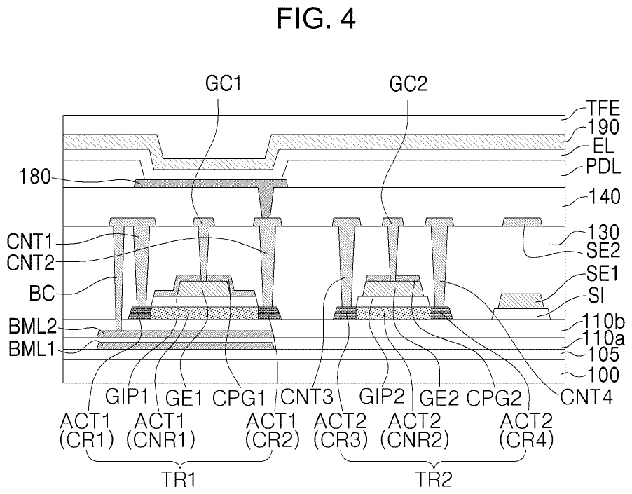

FIG. 4 is a schematic cross-sectional view illustrating a display device according to one or more embodiments. More detailed descriptions on elements and structures substantially the same as or similar to those described with reference to FIGS. 1 and 2 may not be provided.

Referring to FIG. 4, the display device may include a first transistor element TR1 and a second transistor element TR2. The display device may further include rear metal layers BML1 and BML2 under the first transistor element TR1 to overlap the first transistor element TR1 in a thickness direction. The rear metal layers BML1 and BML2 may include the metal as described in one or more embodiments or alloy.

According to one or more embodiments, a first rear metal layer BML1 may be on the barrier layer 105, and a first buffer layer 110a covering the first rear metal layer BML1 may be on the barrier layer 105. A second rear metal layer BML2 may be on the first buffer layer 110a, and a second buffer layer 110b covering the second rear metal layer BML2 may be on the first buffer layer 110a.

The rear metal layers BML1 and BML2 may be provided as blocking layers of external light with respect to the driving transistor. The rear metal layers BML1 and BML2 may be provided as bias electrodes. In one or more embodiments, the rear metal layers BML1 and BML2 may be island-shaped (e.g., substantially island-shaped) floating electrodes separated from other wirings or electrodes. In one or more embodiments, the rear metal layers BML1 and BML2 may be provided as a back-gate or a source-sink electrode.

The first transistor element TR1 and the second transistor element TR2 may be on the second buffer layer 110b. The first transistor element TR1 and the second transistor element TR2 may serve as a driving transistor and a switching transistor of each pixel of the display device, respectively.

The first transistor element TR1 may include a first active layer ACT1, a first gate insulation pattern GIP1, a first gate electrode GE, and a first capping gate CPG1. The first active layer ACT1 may include first contact region CR1, second contact region CR2, and a first channel region CNR1 between the first and second contact regions CR1 and CR2. The first transistor element TR1 may have a structure substantially the same as or similar to the structure of the transistor element as described with reference to FIG. 1.

As described with reference to FIG. 1, the first gate insulation pattern GIP1 may partially cover a top surface of the first active layer ACT1, and the first gate electrode GE1 may partially cover a top surface of the first gate insulation pattern GIP1. The first gate insulation pattern GIP1 may include an overlap portion OR and shoulder portions LR1 and LR2 (see FIG. 1).

The first capping gate CPG1 may cover top surfaces of the shoulder portions LR1 and LR2 (e.g., a top surface of the shoulder portion LR1 and a top surface of the shoulder portion LR2) and a surface of the first gate electrode GE1.

The first contact electrode CNT1 and the second contact electrode CNT2 may penetrate the insulating interlayer 130 and may be in contact with or electrically connected to the first contact region CR1 and the second contact region CR2, respectively. A first gate contact GC1 may penetrate the insulating interlayer 130 and the first capping gate CPG1 to be in contact with the first gate electrode GE1.

In one or more embodiments, the display device may further include a rear contact BC that may penetrate the insulating interlayer 130 and the second buffer layer 110b to be in contact with or electrically connected to the second rear metal layer BML2. In one or more embodiments, the rear contact BC may be connected to the first contact electrode CNT1 provided as a source contact. In one or more embodiments, the rear contact BC may serve as a source-sink contact.

In one or more embodiments, a double gate structure may be implemented by the first gate contact GC1. For example, the first gate contact GC1 may be connected to the first rear metal layer BML1 or the second rear metal layer BML2. In one or more embodiments, the first gate contact GC1 may be connected to the first rear metal layer BML1 by an additional wiring/contact.

The second transistor element TR2 may include a second active layer ACT2, a second gate insulation pattern GIP2, and a second gate electrode GE2. The second transistor element TR2 may further include a second capping gate CPG2 on the second gate electrode GE2.

In one or more embodiments, the second active layer ACT2 may include an oxide semiconductor substantially the same as or similar to the oxide semiconductor of the first active layer ACT1. The second active layer ACT2 may include a third contact region CR3 and a fourth contact region CR4 and may include a second channel region CNR2 between the third contact region CR3 and the fourth contact region CR4. The third contact region CR3 and the fourth contact region CR4 may serve as a source region and a drain region of the second transistor element TR2, respectively.

The second gate insulation pattern GIP2 and the second gate electrode GE2 may be sequentially stacked on the second channel region CNR2. A portion of the second active layer ACT2 overlapping the second gate insulation pattern GIP2 and the second gate electrode GE2 may substantially function as the second channel region CNR2.

The second capping gate CPG2 may cover a top surface of the second gate electrode GE2. In one or more embodiments, the second capping gate CPG2 may not be in contact with the second gate insulation pattern GIP2. Accordingly, in the second transistor element TR2, an injection barrier effect at the shoulder portion of the gate insulation pattern GIP as described in one or more embodiments may be suppressed or reduced, and a voltage-current sensitivity may be relatively increased or enhanced.

In one or more embodiments, the second capping gate CPG2 may contact the top surface of the second gate electrode GE2 and may not contact a side surface of the second gate electrode GE2.

The second gate insulation pattern GIP2, the second gate electrode GE2, and the second capping gate CPG2 may include a material substantially the same as or similar to the material of the first gate insulation pattern GIP1, the first gate electrode GE1, and the first capping gate CPG1, respectively.

The third contact electrode CNT3 and the fourth contact electrode CNT4 may penetrate the insulating interlayer 130 and may be in contact with or electrically connected to the third contact region CR3 and the fourth contact region CR4, respectively. A second gate contact GC2 may penetrate the insulating interlayer 130 and the second capping gate CPG2 to be in contact with the top surface of the second gate electrode GE2.

In one or more embodiments, a sub-insulation layer SI spaced and/or apart (e.g., spaced apart or separated) from the gate insulation patterns GIP1 and GIP2 may be formed or provided on the second buffer layer 110b. The sub-insulation layer SI may include an insulating (e.g., electrically insulating) material substantially the same as or similar to the insulating material of the gate insulation patterns GIP1 and GIP2.

A first sub-electrode SE1 spaced and/or apart (e.g., spaced apart or separated) from the gate electrodes GE1 and GE2 may be on the sub-insulation layer SI. The first sub-electrode SE1 may include substantially the same conductive (e.g., electrically conductive) material as the conductive material of the gate electrodes GE1 and GE2.

A second sub-electrode SE2 being opposite to (e.g., facing) the first sub-electrode SE1 with the insulating interlayer 130 therebetween may be on the insulating interlayer 130. A storage capacitor Cst may be defined by the first and second sub-electrodes SE1 and SE2. The second sub-electrode SE2 may include substantially the same conductive (e.g., electrically conductive) material as the conductive material of the contact electrodes CNT1, CNT2, CNT3, and CNT4.

The planarization layer 140 may cover the contact electrodes CNT1, CNT2, CNT3, and CNT4, and the second sub-electrode SE2. The pixel defining layer PDL and the light-emitting element including the first electrode 180, the light-emitting portion EL, and the second electrode 190 as described with reference to FIG. 1 may be on the planarization layer 140. The encapsulation layer TFE may be on the light-emitting element.

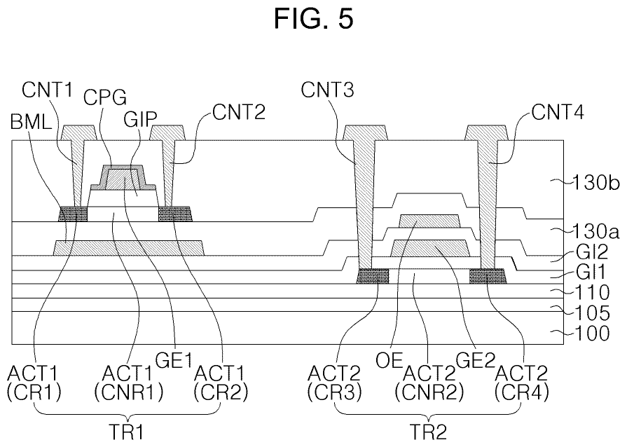

FIG. 5 is a schematic cross-sectional view illustrating a display device according to one or more embodiments. For example, FIG. 5 illustrates a display device having a hybrid structure including both (e.g., simultaneously) an oxide semiconductor active (e.g., electrically active) layer and a silicon-based active (e.g., electrically active) layer. For convenience of illustration, illustrations of the light-emitting element, the pixel defining layer PDL, and the encapsulation layer TFE may not be provided in FIG. 5.

More detailed descriptions on elements and structures that are substantially the same as or similar to the elements and structures as described with reference to FIGS. 1, 2, and 4 may not be provided.

Referring to FIG. 5, the display device may include a first transistor element TR1 and a second transistor element TR2. The first transistor element TR1 may have substantially the same elements and structures as the elements and structures of the transistor element as described with reference to FIG. 1 or the first transistor element TR1 as described with reference to FIG. 4.

The second transistor device TR2 may include a second active layer ACT2 and a second gate electrode GE2, and the second active layer ACT2 may be provided at a lower level than the level of the first active layer ACT1. According to one or more embodiments, the second active layer ACT2 and the second gate electrode GE2 may be provided at a lower level than the level of the first active layer ACT1.

The second active layer ACT2 may include a silicon-based semiconductor material (e.g., amorphous (e.g., non-crystalline) silicon and/or polysilicon). The third and fourth contact regions CR3 and CR4 included in the second active layer ACT2 may be formed or provided as a p-doped region or a p+ doped region. A portion of the second active layer ACT2 between the third and fourth contact regions CR3 and CR4 may be provided as a second channel region CNR2 including the silicon-based semiconductor material.

A first gate insulation layer GI1 covering the second active layer ACT2 may be formed or provided on the buffer layer 110. The first gate insulation layer GI1 may substantially cover an entire top surface of the buffer layer 110.

The second gate electrode GE2 may be on the first gate insulation layer GI1 to overlap the second channel region CNR2 in a thickness direction.

The second gate insulation layer GI2 may be formed or provided on the first gate insulation layer GI1 to cover the second gate electrode GE2. An overlap electrode OE may be on the second gate insulation layer GI2. The overlap electrode OE may overlap the second gate electrode GE2 in the thickness direction or in a height direction with the second gate insulation layer GI2 therebetween.

In one or more embodiments, the overlap electrode OE may serve as an upper gate electrode of the second transistor element TR2. In one or more embodiments, a storage capacitor may be formed or provided by the overlap electrode OE, the second gate insulation layer GI2, and the second gate electrode GE2.

A lower insulating interlayer 130a may be formed or provided on the second gate insulation layer GI2 to cover the overlap electrode OE. In one or more embodiments, a rear metal layer BML may be further formed or provided on the second gate insulation layer GI2 together with the overlap electrode OE. In this case, the lower insulating interlayer 130a may cover the rear metal layer BML and the overlap electrode OE.

The first transistor element TR1 as described with reference to FIG. 1 or 4 may be on the lower insulating interlayer 130a. The rear metal layer BML may be under the first transistor element TR1 to overlap the first active layer ACT1.

An upper insulating interlayer 130b may be formed or provided on the lower insulating interlayer 130a to cover the first transistor element TR1. Contact electrodes CNT1, CNT2, CNT3, and CNT4 may penetrate the upper insulating interlayer 130b to be in contact with or connected to the contact regions CR1, CR2, CR3, and CR4, respectively.

The first and second gate insulation layers GI1 and GI2 may include an insulating (e.g., electrically insulating) material substantially the same as or similar to the insulating material of the gate insulation pattern GIP. The upper insulating interlayer 130b and the lower insulating interlayer 130a may include an insulating (e.g., electrically insulating) material substantially the same as or similar to the insulating material of the insulating interlayer 130 as described in one or more embodiments.

The planarization layer 140, the pixel defining layer PDL, the light-emitting element including the first electrode 180, the light-emitting portion EL, and the second electrode 190, and the encapsulation layer TFE as illustrated in FIG. 4 may be formed or provided on the upper insulating interlayer 130b. The first electrode 180 may be in contact with or connected to the second contact electrode CNT2 or the fourth contact electrode CNT4.

In one or more embodiments, the first transistor element TR1 may serve as a driving transistor of each pixel, and the second transistor element TR2 may serve as a switching transistor of each pixel. In one or more embodiments, the first transistor element TR1 may serve as a switching transistor, and the second transistor element TR2 may serve as a driving transistor.

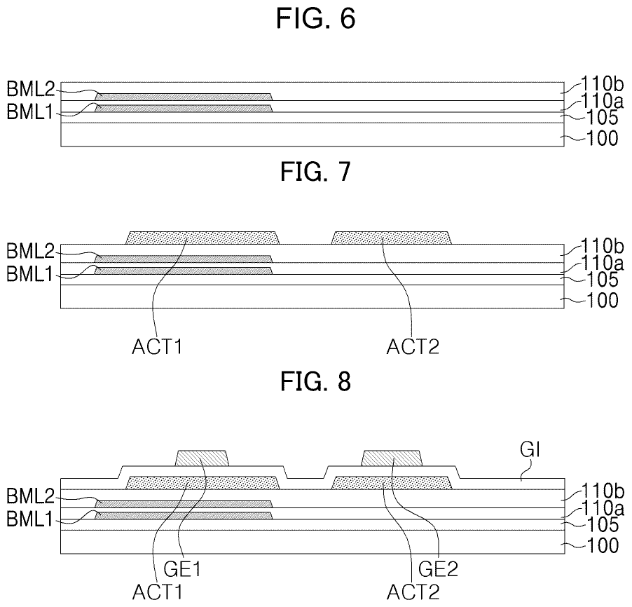

FIGS. 6 to 12 are schematic cross-sectional views describing a method of manufacturing a display panel or a display device according to one or more embodiments. For example, FIGS. 6 to 12 are cross-sectional views illustrating a method of manufacturing the display device as illustrated in FIG. 4. More detailed descriptions on the materials that are substantially the same as or similar to the materials as described with reference to FIGS. 1 and 4 may not be provided. For convenience of descriptions, illustrations of the sub-insulation layer SI and the sub-electrodes SE1 and SE2 as illustrated in FIG. 4 may not be provided.

Referring to FIG. 6, the barrier layer 105 may be formed or provided on the base substrate 100, and the first rear metal layer BML1 may be formed or provided on the barrier layer 105. The first buffer layer 110a may be formed or provided on the first rear metal layer BML1, and the second buffer layer 110b covering the first rear metal layer BML1 may be formed or provided on the first buffer layer 110a.

The conductive (e.g., electrically conductive) layers including the metal as described in one or more embodiments or alloy may be formed or provided by a deposition process, such as a sputtering process, and then the conductive layers may be patterned by a photo-lithography process to form or provide the first and second rear metal layers BML1 and BML2. The barrier layer 105 and the buffer layers 110a and 110b may be formed or provided by, e.g., a deposition process, such as a chemical vapor deposition (CVD) process, to include the inorganic insulating material as described in one or more embodiments.

Referring to FIG. 7, the first active layer ACT1 and the second active layer ACT2 may be formed or provided on the second buffer layer 110b. For example, an oxide semiconductor layer may be formed or provided on the second buffer layer 110b by a sputtering process using a target including indium (In), tin (Sn), gallium (Ga), and/or zinc (Zn).

The oxide semiconductor layer may be patterned by a photo-lithography process to form or provide the first active layer ACT1 and the second active layer ACT2. The first active layer ACT1 may be formed or provided to overlap the rear metal layers BML1 and BML2 in the thickness direction.

Referring to FIG. 8, a gate insulation layer GI may be formed or provided on the buffer layer 110, and then the first gate electrode GE1 and the second gate electrode GE2 may be formed or provided on the gate insulation layer GI.

The gate insulation layer GI may be formed or provided by a deposition process, such as a CVD process, to include the inorganic insulating material as described in one or more embodiments. Thereafter, a gate electrode layer may be formed or provided on the gate insulation layer GI by a deposition process, such as a sputtering process, to include the metal as described in one or more embodiments.

The gate electrode layer may be patterned by a photo-lithography process using a photoresist layer to form or provide the first gate electrode GE1 and the second gate electrode GE2.

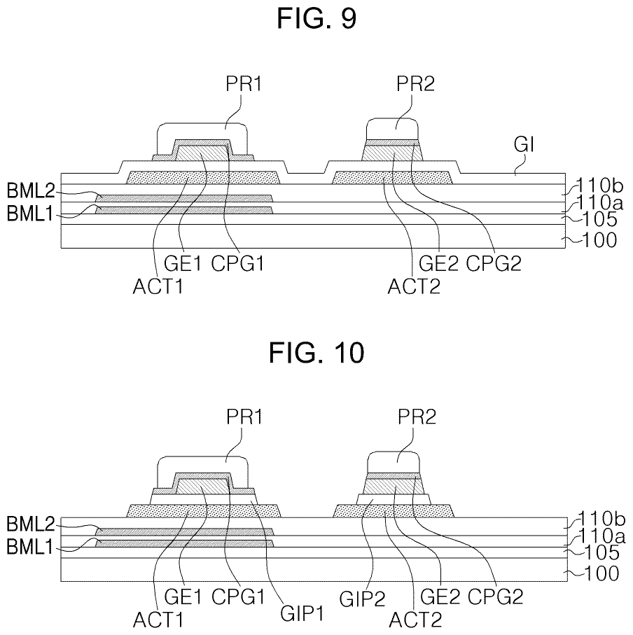

Referring to FIG. 9, a capping gate layer covering the first gate electrode GE1 and the second gate electrode GE2 may be formed or provided on the gate insulation layer GI. The capping gate layer may be formed or provided by a deposition process, such as a sputtering process, to include the metal oxide, the transparent conductive oxide, and/or the oxide semiconductor material as described in one or more embodiments.

A photoresist layer may be formed or provided on the capping gate layer, and then a first photoresist pattern PR1 and a second photoresist pattern PR2 may be formed or provided by exposure and development processes.

The first photoresist pattern PR1 may be formed or provided on the first gate electrode GE1 to have a width greater than a maximum width of the first gate electrode GE1. The second photoresist pattern PR2 may be formed or provided on the second gate electrode GE2 to have a width equal to or less than a maximum width of the second gate electrode GE2.

Thereafter, the capping gate layer may be partially removed using the first photoresist pattern PR1 and the second photoresist pattern PR2 as etching masks. Accordingly, the first capping gate CPG1 covering the first gate electrode GE1 and partially covering the gate insulation layer GI may be formed or provided. The second capping gate CPG2 may be formed or provided on a top surface of the second gate electrode GE2. The second capping gate CPG2 may not be in contact with the gate insulation layer GI.

Referring to FIG. 10, the gate insulation layer GI may be partially removed by using the first and second photoresist patterns PR1 and PR2 as etching masks again. Accordingly, the first gate insulation pattern GIP1 may be formed or provided under the first gate electrode GE1, and the second gate insulating pattern GIP2 may be formed or provided under the second gate electrode GE2.

In the etching process, the capping gates CPG1 and CPG2 and the gate electrodes GE1 and GE2 may also function as etching masks. Accordingly, the first gate insulation pattern GIP1 may be formed or provided to include the shoulder portions LR1 and LR2 (see FIG. 1) which are in contact with the first capping gate CPG1. The second gate insulation pattern GIP2 may be formed or provided to be physically separated from or spaced and/or apart (e.g., spaced apart or separated) from the second capping gate CPG2 with the second gate electrode GE2 therebetween.

After the etching process as described in one or more embodiments, the first and second photoresist patterns PR1 and PR2 may be removed BY a strip process and/or an ashing process.

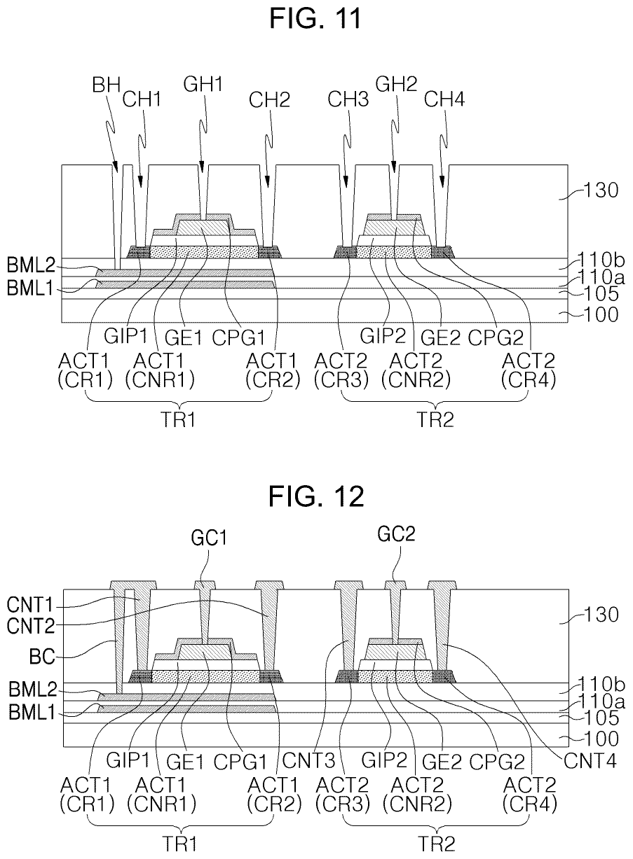

Referring to FIG. 11, an insulating interlayer 130 covering the active layers ACT1 and ACT2, the gate insulation patterns GIP1 and GIP2, the gate electrodes GE1 and GE2, and the capping gates CPG1 and CPG2 may be formed or provided on the second buffer layer 110b. The insulating interlayer 130 may be formed or provided by a deposition process, such as a CVD process, to include the inorganic insulating material as described in one or more embodiments.

During the formation or arrangement of the insulating interlayer 130, hydrogen contained in the insulating interlayer 130 may be diffused or transferred to internal damage sites induced in the active layers ACT1 and ACT2 by the etching process to form or provide the contact regions CR1, CR2, CR3, and CR4.

Accordingly, the first transistor element TR1 that includes the first active layer ACT1 including the first and second contact regions CR1 and CR2 and the first channel region CNR1, the first gate insulation pattern GIP1, the first gate electrode GE1, and the first capping gate CPG1 may be formed or provided. The second transistor element TR2 that includes the second active layer ACT2 including the third and fourth contact regions CR3 and CR4 and the second channel region CNR2, the second gate insulation pattern GIP2, the second gate electrode GE2, and the second capping gate CPG2 may be formed or provided.

Thereafter, contact holes may be formed or provided by partially etching the insulating interlayer 130 by, for example, an anisotropic etching process, such as a dry etching process. According to one or more embodiments, a first contact hole CH1 and a second contact hole CH2 exposing the first contact region CR1 and the second contact region CR2, respectively, and a third contact hole CH3 and a fourth contact hole CH4 exposing the third contact region CR3 and the fourth contact region CR4, respectively, may be formed or provided.

In one or more embodiments, a first gate contact hole GH1 exposing a top surface of the first gate electrode GE1 and a second gate contact hole GH2 exposing a top surface of the second gate electrode GE2 may also be formed or provided by substantially the same etching process as the etching process for the first to fourth contact holes CH1, CH2, CH3, and CH4.

The capping gates CPG1 and CPG2 may be additionally partially etched to form or provide the gate contact holes GH1 and GH2. Accordingly, the first to fourth contact holes CH1, CH2, CH3, and CH4 may have an over-etched shape, and may be partially inserted into upper portions of the contact regions CR1, CR2, CR3, and CR4 of the active layers ACT1 and ACT2.

In one or more embodiments, a rear contact hole BH may also be formed or provided by substantially the same etching process as the etching process for the first to fourth contact holes CH1, CH2, CH3, and CH4. For example, the rear contact hole BH may penetrate the insulating interlayer 130 and the first buffer layer 110b to expose a top surface of the second rear metal layer BML2.

Referring to FIG. 12, a metal layer including the metal as described in one or more embodiments and filling the contact holes may be formed or provided on a top surface of the insulating interlayer 130. The metal layer may be partially etched by a photo-lithography process to form or provide the first contact electrode CNT1, the second contact electrode CNT2, the third contact electrode CNT3, and the fourth contact electrode CNT4 filling the first contact hole CH1, the second contact hole CH2, the third contact hole CH3, and the fourth contact hole CH4, respectively, and being in contact with or electrically connected to the first contact region CR1, the second contact region CR2, the third contact region CR3, and the fourth contact region CR4, respectively.

The first and second gate contacts GC1 and GC2 filling the first and second gate contact holes GH1 and GH2, respectively, and contacting the first and second gate electrodes GE1 and GE2, respectively, may be formed or provided together from the metal layer.

The rear contact BC filling the rear contact hole BH and being in contact with or electrically connected to the second rear metal layer BML2 may be formed or provided together from the metal layer.

Referring back to FIG. 4, the planarization layer 140 covering the contacts and the contact electrodes may be formed or provided on the insulating interlayer 130. The planarization layer 140 may be formed or provided by a coating process, for example, a spin coating process, to include the organic insulating material as described in one or more embodiments.

The planarization layer 140 may be partially etched to form or provide a via hole exposing a top surface of the second contact electrode CNT2. An electrode layer including the conductive (e.g., electrically conductive) material as described in one or more embodiments and filling the via hole may be formed or provided on the planarization layer 140. The electrode layer may be partially etched to form or provide the first electrode 180.

The pixel defining layer PDL may be formed or provided on the planarization layer 140. The pixel defining layer PDL may cover a peripheral portion of the first electrode 180.

In one or more embodiments, the pixel defining layer PDL may be formed or provided by exposure and development processes after coating a photosensitive organic material, such as a polysiloxane resin, a polyimide resin, and/or an acrylic resin. In one or more embodiments, the pixel defining layer PDL may be formed or provided by a printing process, such as an inkjet printing process, using a polymer material and/or an inorganic material.

The light-emitting portion EL may be formed or provided on a top surface of the first electrode 180 exposed by the pixel defining layer PDL and a sidewall of the pixel defining layer PDL.

The light-emitting portion EL may be formed or provided by a thermal deposition, a vaporization deposition, a vacuum deposition, a spin coating, an inkjet printing, a laser printing, a casting, a laser thermal transfer, and/or the like to include the organic light-emitting material as described in one or more embodiments.

As described in one or more embodiments, the light-emitting portion EL may include the hole transport layer, the emission layer, and the electron transport layer.

In one or more embodiments, the hole transport layer and the electron transport layer may be continuously (e.g., substantially continuously) and commonly formed or provided throughout a plurality of pixels or the first electrodes 180, and the pixel defining layer PDL. In one or more embodiments, the emission layer may be selectively patterned for each first electrode 180 of an individual pixel.

The second electrode 190 serving as a common electrode may be formed or provided on the pixel defining layer PDL and the light emitting part EL, and then the encapsulation layer TFE protecting the pixels and the second electrode 190 may be formed or provided. The encapsulation layer TFE may be formed or provided to include a multi-layered structure of an inorganic insulation (e.g., electrical insulation) layer and an organic insulation (e.g., electrical insulation) layer. For example, the encapsulation layer TFE may be formed or provided in a sequential stacked structure of a first inorganic insulation (e.g., electrical insulation) layer, an organic insulation (e.g., electrical insulation) layer, and a second inorganic insulation (e.g., electrical insulation) layer.

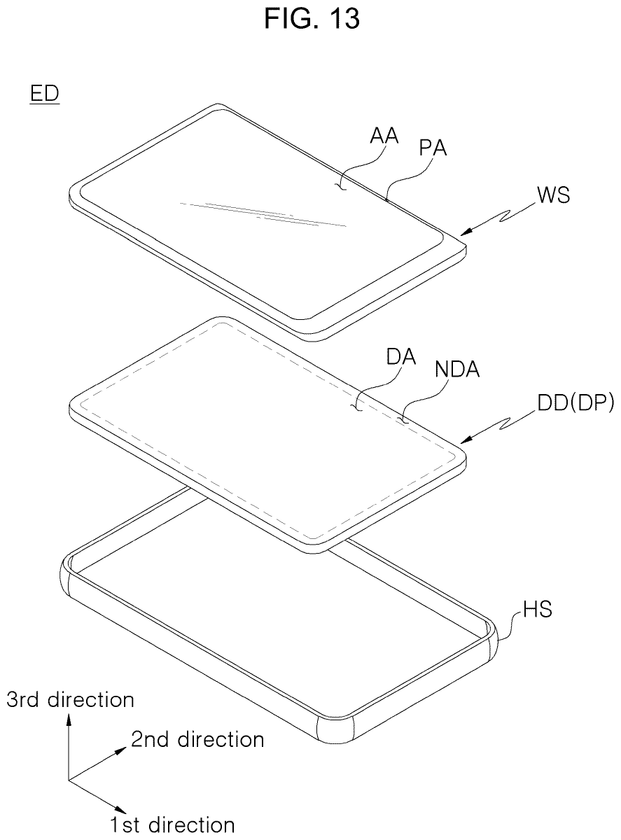

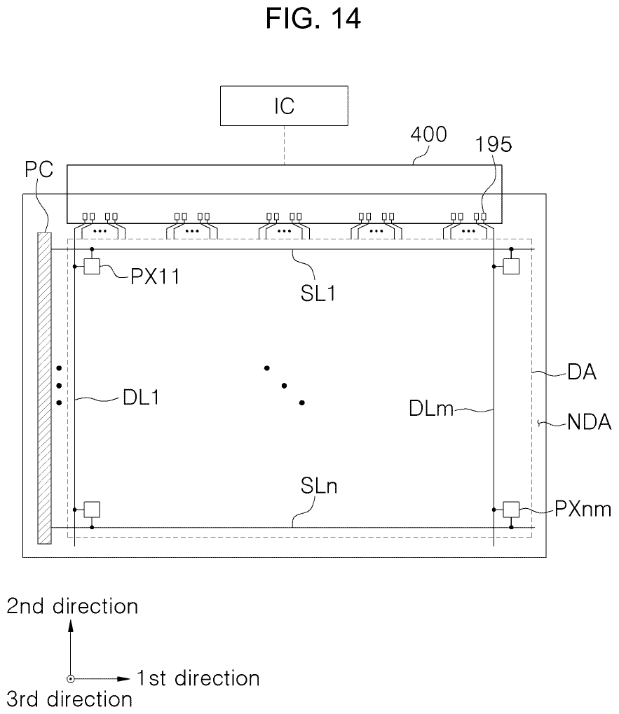

FIG. 13 is an exploded perspective view illustrating an electronic device according to one or more embodiments. FIG. 14 is a schematic plan view illustrating an arrangement of pixels of a display device included in an electronic device according to one or more embodiments.

In FIGS. 13 and 14, the first direction and the second direction may refer to two directions parallel (e.g., substantially parallel) to and perpendicular (e.g., substantially perpendicular) to a window structure WS and/or a display surface of a display panel DP. For example, the first direction may correspond to an X-direction (a row direction) of a display device DD or the display panel DP, and the second direction may correspond to a Y-direction (a column direction) of the display device DD or the display panel DP.

The third direction may be perpendicular (e.g., substantially perpendicular) to the first direction and the second direction. The third direction may correspond to a Z direction (a thickness direction) of the display device DD or the display panel DP.

Referring to FIG. 13, an electronic device ED may include the window structure WS, the display device DD, and a housing HS. The display device DD may include the display panel DP including the transistor elements and the light-emitting portion as described in one or more embodiments. The housing HS, the display device DD, and the window structure WS may be sequentially stacked in the third direction.

The window structure WS may provide, for example, an external display surface or a viewing surface (e.g., a display surface of a smartphone) recognized by a user of a display, and may include a transparent (e.g., substantially transparent) material film. For example, the window structure WS may include glass (e.g., ultra-thin glass (UTG)), a hard coating film, a plastic film, and/or the like.

An outer surface of the window structure WS may include an active area AA and a peripheral area PA. The active area AA may provide a surface from which an image of the display device DD is displayed and to which a user's touch/command is input. The peripheral area PA may substantially correspond to a bezel area of the electronic device ED.

The display device DD or the display panel DP may include a display area DA and a non-display area NDA. The display area DA of the display panel DP may substantially correspond to or overlap the active area AA of the window structure WS. The non-display area NDA of the display panel DP may substantially correspond to or overlap the peripheral area PA of the window structure WS.

For example, a sensor structure for touch sensing and/or fingerprint sensing may be within the display panel DP or between the window structure WS and the display panel DP.

The housing HS may be provided as a frame structure or a rear housing of the display device DD or the electronic device ED. A cover panel may be between the housing HS and the display panel DP. The housing HS or the cover panel may include a plate (e.g., an SUS plate) that supports the display panel DP, a printed circuit board 400 (see FIG. 14), and/or the like. The housing HS or the cover panel may include an elastic body to absorb shock of the display device DD.

Referring to FIG. 14, a plurality of pixels PX11 to PXnm may be arranged or provided in the display area DA of the display panel DP.

According to one or more embodiments, a pixel circuit including scan lines (or gate lines) SL1 to SLn that forms or provides first to n^{th} rows and data lines DL1 to DLm that forms or provides first to m^{th} columns may be arranged or provided on the base substrate 100 of the display device DD or the display panel DP. Each of the pixels PX11 to PXnm may be connected to a scan line of a corresponding row among a plurality of the scan lines SL1 to SLn and a data line of a corresponding column among a plurality of the data lines DL1 to DLm.

For example, the scan lines SL1 to SLn may be connected to a gate electrode included in the thin film transistor. The data lines DL1 to DLm may be connected to, for example, a contact electrode (e.g., the first contact electrode CNT1 or the third contact electrode CNT3) provided as the source electrode.

Each of the pixels PX11 to PXnm may include a pixel circuit including the transistor and the light-emitting device as described in one or more embodiments. In one or more embodiments, the pixel circuit may further include wirings, such as a power line, a ground line, and/or the like.

FIG. 14 illustrates that the data lines DL1 to DLm extend in the second direction and the scan lines SL1 to SLn extend in the first direction, but embodiments of the present disclosure are not limited to the construction of FIG. 14.

A peripheral circuit PC may be in the peripheral area PA of the window structure WS or the non-display area NDA of the display device DD. For example, the peripheral circuit PC may include a gate driving circuit. The gate driving circuit may be integrated into the display panel DP through an oxide semiconductor gate (OSG) driver circuit process, an amorphous (e.g., non-crystalline) silicon gate (ASG) driver circuit process, or a polysilicon gate driver (PSG) circuit process.

The electronic device ED or the display device DD may further include a printed circuit board 400. Pads 195 of the pixel circuit (e.g., the data lines) may be arranged or provided at one side of the non-display area NDA. The printed circuit board 400 may be electrically connected to the pixel circuit through the pads 195. For example, the printed circuit board 400 may be electrically connected to the pads 195 by a heating-compression process using a conductive (e.g., electrically conductive) intermediation structure, such as an anisotropic conductive film (ACF).

The pads 195 and a driving circuit element IC may be electrically connected through the printed circuit board 400. The driving circuit element IC may include an integrated circuit chip. In one or more embodiments, the integrated circuit chip may be mounted on the printed circuit board 400 in a chip-on-film (COF) form.

The driving circuit element IC may include a driving circuit of the display device DD and a driving circuit (e.g., an application processor (AP) chip) of the electronic device ED. The driving circuit element IC may further include a circuit board, such as a main board on which a chip including the driving circuit is mounted.

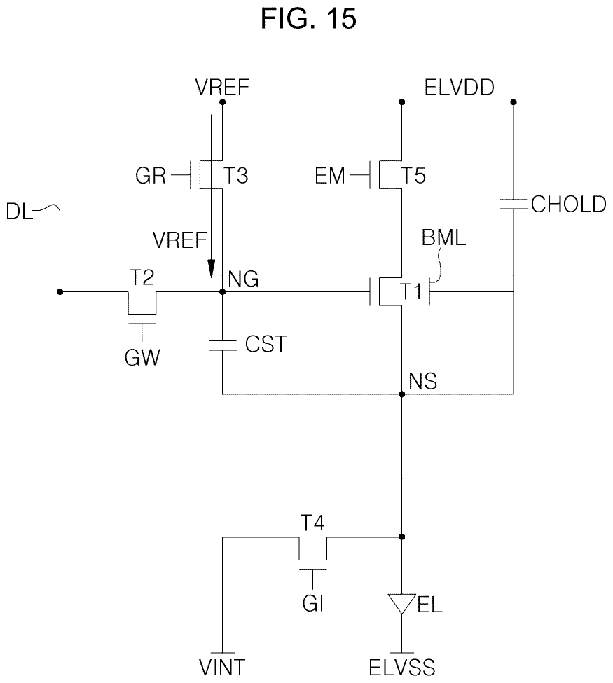

FIG. 15 is a pixel equivalent circuit diagram of a display device according to one or more embodiments.

In FIG. 15, a structure of 5T2C including five thin film transistors and two capacitors for each pixel is illustrated, but the pixel structure of the display device as disclosed herein is not necessarily limited thereto. For example, each pixel may include two or more transistors and may have a structure, such as 2T1C, 5T1C, 6T1C, 6T2C, and 7T1C.

Referring to FIG. 15, each pixel may include a first transistor T1, a second transistor T2, a third transistor T3, a fourth transistor T4, a fifth transistor T5, a storage capacitor CST, a hold capacitor CHOLD, and a light-emitting element including a light-emitting portion EL.

According to one or more embodiments, the first transistor T1 may be a driving transistor including an oxide semiconductor. The transistor element as described with reference to FIG. 1 or FIG. 2 or the first transistor element TR1 as described with reference to FIG. 4 may be applied as the first transistor T1.

The first transistor T1 may generate a driving current that may be supplied to the light-emitting element including the light-emitting portion EL based on a voltage between a gate node NG and a source node NS, e.g., a voltage stored in a storage capacitor CST. The first transistor T1 may include a gate connected to the gate node NG, a first terminal connected to the fifth transistor T5, and a second terminal connected to the source node NS.

In one or more embodiments, the gate connected to the gate node NG may be an upper gate over the active layer of the first transistor T1, and the first transistor T1 may further include the rear metal layer BML under the active layer. The rear metal layer BML may serve as a lower gate of the first transistor T1, and the first transistor T1 may have a double gate structure.

For example, the rear metal layer BML of the first transistor T1 may be connected to the source node NS, and the rear metal layer BML may be maintained at a constant voltage by the hold capacitor CHOLD so that (e.g., such that) driving properties of the first transistor may be improved or enhanced.

The second transistor T2 may transmit a data voltage to the gate node NG in response to a write signal GW. The second transistor T2 may include a gate that receives the write signal GW, a first terminal connected to a data line DL, and a second terminal connected to the gate node NG.

The third transistor T3 may transmit a reference voltage VREF to the gate node NG in response to a reference signal GR. The third transistor T3 may include a gate that receives the reference signal GR, a first terminal connected to a line of the reference voltage VREF, and a second terminal connected to the gate node NG.

The fourth transistor T4 may transmit an initialization voltage VINT to an anode of the light-emitting element including the light-emitting portion EL in response to an initialization signal GI. The fourth transistor T4 may include a gate that receives the initialization signal GI, a first terminal connected to the anode of the light-emitting element, and a second terminal connected to a line of the initialization voltage VINT.

The fifth transistor T5 may connect a line of a first power supply voltage ELVDD (e.g., a high-power supply voltage) to the first terminal of the first transistor T1 in response to an emission signal EM. The fifth transistor T5 may include a gate that receives the emission signal EM, a first terminal connected to a line of the first power supply voltage ELVDD, and a second terminal connected to the first terminal of the first transistor T1.

The storage capacitor CST may be connected between the gate node NG and the source node NS. The storage capacitor CST may include a first electrode connected to the gate node NG and a second electrode connected to the source node NS.

The hold capacitor CHOLD may be connected between the line of the first power supply voltage ELVDD and the source node NS. The hold capacitor CHOLD may include a first electrode connected to the source node NS and a second electrode connected to the line of the first power supply voltage ELVDD.

The light-emitting element may emit a light based on the driving current generated by the first transistor T1. The light-emitting element may include an anode (e.g., the first electrode 180) connected to the fourth transistor T4 and the source node NS and a cathode (e.g., the second electrode 190) connected to a line of a second power supply voltage ELVSS (e.g., a low power supply voltage).

In one or more embodiments, at least one selected from among the second to fifth transistors T2 to T5 may include the second transistor element TR2 as described with reference to FIG. 4.

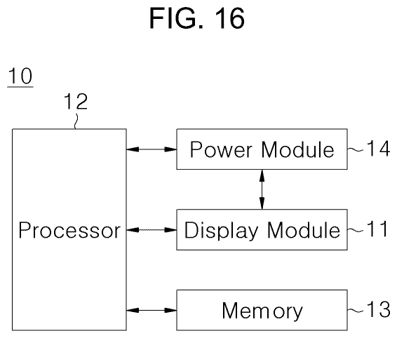

FIG. 16 is a block diagram of an electronic device in accordance with one or more embodiments.

Referring to FIG. 16, an electronic device 10 according to one or more embodiments may include a display module 11, a processor 12, a memory 13, and a power module 14.

The processor 12 may include a central processing unit (CPU), an application processor (AP), a graphic processing unit (GPU), a communication processor (CP), an image signal processor (ISP), and/or a controller.

Data information for an operation of the processor 12 or the display module 11 may be stored in the memory 13. If (e.g., when) the processor 12 executes an application stored in the memory 13, an image data signal and/or an input control signal may be transmitted to the display module 11, and the display module 11 may process the received signal and output image information through a display screen.

The power module 14 may include a power supply module, such as a power adapter and/or a battery device, and a power conversion module that converts a power supplied by the power supply module to a generate power required for the operation of the electronic device 10.

At least one selected from among the components of the electronic device 10 as described in one or more embodiments may be included in the display device according to one or more embodiments. In one or more embodiments, one or more of individual modules functionally included in one module may be included in the display device, and others may be provided separately from the display device. For example, the display module 11 may include the display device, and the processor 12, the memory 13, and the power module 14 may be provided in the form of another device in the electronic device 10 different from the display device.

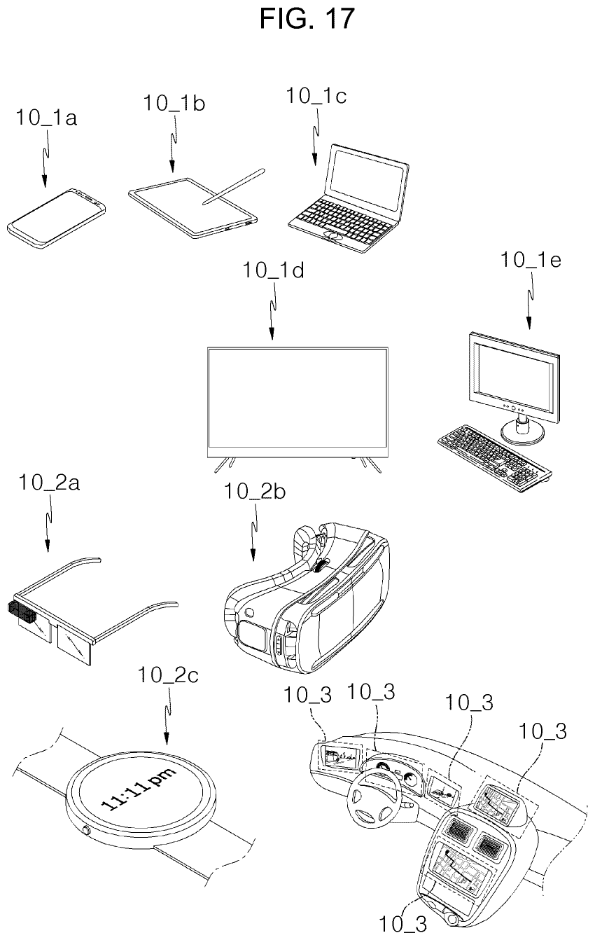

FIG. 17 is a schematic diagram of electronic devices in accordance with one or more embodiments.

Referring to FIG. 17, non-limiting examples of one or more suitable electronic devices to which the display device according to one or more embodiments is applied may include an electronic device to display an image, such as a smartphone 10_1a, a tablet PC 10_1b, a laptop 10_1c, a TV 10_1d, a desk monitor 10_1e, and/or the like; a wearable electronic device including a display module, such as smart glasses 10_2a, a head mounted display 10_2b, a smart watch 10_2c, and/or the like; a vehicle electronic device 10_3 including a display module, such as a center information display (CID) at a vehicle instrument panel, a center fascia, a dashboard, and/or the like, a head-up display, a room mirror display, and/or the like. The electronic device may include a virtual reality glass and/or an augmented reality glass.

It will be understood by one of ordinary skill in the art to which the present disclosure belongs that the present disclosure may be implemented in one or more suitable forms without changing the spirit and scope of the present disclosure. Therefore, it will be understood that the one or more embodiments as described in the present disclosure are illustrative rather than being restrictive in all aspects. It will be understood that the scope of the present disclosure are defined by the scope of the appended claims and equivalents thereof rather than the detailed description as described above and all modifications and alterations derived from the appended claims and their equivalents fall within the scope of the present disclosure.

What is claimed is:

1. A display device, comprising:
a base substrate;
a light-emitting element on the base substrate; and
transistor elements electrically connected to the light-emitting element on the base substrate, the transistor elements comprising a first transistor element that comprises:
a first active layer comprising an oxide semiconductor;
a first gate insulation pattern partially covering a top surface of the first active layer;
a first gate electrode partially covering a top surface of the first gate insulation pattern; and
a first capping gate covering a surface of the first gate electrode and the top surface of the first gate insulation pattern.

2. The display device as claimed in claim 1, wherein the first capping gate comprises a material having a higher resistivity than a resistivity of the first gate electrode.

3. The display device as claimed in claim 2, wherein the first capping gate comprises titanium oxide, tantalum oxide, molybdenum oxide, a transparent conductive oxide (TCO), or an oxide semiconductor material.

4. The display device as claimed in claim 1, wherein the first gate insulation pattern comprises an overlap portion covered by the first gate electrode, and a first shoulder portion and a second shoulder portion which are not covered by the first gate electrode, and
the first shoulder portion and the second shoulder portion are opposite to each other with the overlap portion therebetween.

5. The display device as claimed in claim 4, wherein the first capping gate contacts a top surface of the first shoulder portion and a top surface of the second shoulder portion.

6. The display device as claimed in claim 5, wherein the first capping gate is continuously provided on the top surface of the first shoulder portion, a side surface of the first gate electrode, a top surface of the first gate electrode, and the top surface of the second shoulder portion.

7. The display device as claimed in claim 4, wherein the first active layer has a width greater than a width of the first gate insulation pattern, and
the first active layer comprises a first channel region overlapping the first gate insulation pattern, a first contact region protruding from the first shoulder portion, and a second contact region protruding from the second shoulder portion.

8. The display device as claimed in claim 7, further comprising a first contact electrode and a second contact electrode that are electrically connected to the first contact region and the second contact region, respectively.

9. The display device as claimed in claim 8, further comprising a first gate contact penetrating the first capping gate and contacting a top surface of the first gate electrode.

10. The display device as claimed in claim 1, wherein the first transistor element is provided as a driving transistor.

11. The display device as claimed in claim 1, wherein the transistor elements further comprise a second transistor element, the second transistor element comprising:
a second active layer;
a second gate insulation pattern partially covering a top surface of the second active layer;
a second gate electrode on the second gate insulation pattern; and
a second capping gate on a top surface of the second gate electrode, the second capping gate being not in contact with the second gate insulation pattern.

12. The display device as claimed in claim 11, wherein the second capping gate does not cover a side surface of the second gate electrode.

13. The display device as claimed in claim 11, wherein the second active layer comprises the oxide semiconductor.

14. The display device as claimed in claim 11, wherein the second transistor element is provided as a switching transistor.

15. A method of manufacturing a display device, comprising:
providing a first active layer comprising an oxide semiconductor and a second active layer on a base substrate;
providing a gate insulation layer covering the first active layer and the second active layer on the base substrate;
providing a first gate electrode and a second gate electrode that are overlapping the first active layer and the second active layer, respectively, on the gate insulation layer;
providing a capping gate layer covering the first gate electrode and the second gate electrode on the gate insulation layer;
providing a first photoresist pattern covering the first gate electrode and having a width greater than a maximum width of the first gate electrode, and a second photoresist pattern overlapping the second gate electrode and having a width less than a maximum width of the second gate electrode on the capping gate layer;
etching the capping gate layer utilizing the first photoresist pattern and the second photoresist pattern as a first set of etching masks to provide a first capping gate covering the first gate electrode and a second capping gate on a top surface of the second gate electrode;
etching the gate insulation layer to provide a first gate insulation pattern between the first gate electrode and the first active layer and a second gate insulation pattern between the second gate electrode and the second active layer; and
providing a light-emitting element electrically connected to the first active layer.

16. The method as claimed in claim 15, wherein the etching of the gate insulation layer comprises utilizing the first capping gate and the second capping gate as a second set of etching masks together with the first photoresist pattern and the second photoresist pattern.

17. The method as claimed in claim 15, wherein the second active layer comprises the oxide semiconductor.

18. The method as claimed in claim 15, wherein the capping gate layer is provided to have a resistivity greater than a resistivity of the first gate electrode and the second gate electrode.

19. An electronic device, comprising:
a display device;
a memory; and
a processor to execute data included in the memory and control an operation of the display device, wherein the display device comprises:
a base substrate;
a light-emitting element on the base substrate; and
a transistor element electrically connected to the light-emitting element on the base substrate, the transistor element comprising:
an active layer including an oxide semiconductor;
a gate insulation pattern partially covering a top surface of the active layer;
a gate electrode partially covering a top surface of the gate insulation pattern; and
a capping gate covering a surface of the gate electrode and the top surface of the gate insulation pattern.

20. The electronic device as claimed in claim 19, wherein the electronic device comprises a virtual reality glass, an augmented reality glass, a smart phone, a tablet PC, a laptop, a TV, a desk monitor, smart glasses, a head-mounted display, a smart watch, or a vehicle display.
